(19) United States
(12) Patent Application Publication
(10) Pub. No.: US 2014/0035167 A1
(43) Pub. Date: Feb. 6, 2014

(54) METHOD FOR PRODUCING A BONDING PAD FOR THERMOCOMPRESSION BONDING, AND BONDING PAD

(71) Applicant: Robert Bosch GmbH, Stuttgart (DE)

(72) Inventors: Christoph Schelling, Stuttgart (DE); David Borowsky, Gerlingen (DE)

(73) Assignee: Robert Bosch GmbH, Stuttgart (DE)

(21) Appl. No.: 13/954,346

(22) Filed: Jul. 30, 2013

(30) Foreign Application Priority Data
Aug. 1, 2012 (DE) 10 2012 213 566.9

(51) Int. Cl. H01L 21/48; H01L 23/48

(52) U.S. Cl. CPC H01L 21/4814; H01L 23/48
USPC 257/782; 438/612

(57) ABSTRACT

A method produces a bonding pad for thermocompression bonding. The method includes providing a carrier material having semiconductor structures, wherein an outermost edge layer of the carrier material is a wiring metal layer configured to make electrical contact with the semiconductor structures. The method also includes depositing a single-layered bonding metal layer directly on a surface of the wiring metal layer to produce the bonding pad.

This application claims priority under 35 U.S.C. §119 to patent application no. DE 10 2012 213 566.9, filed on Aug. 1, 2012 in Germany, the disclosure of which is incorporated herein by reference in its entirety.

### BACKGROUND

The present disclosure relates to a method for producing a bonding pad for thermocompression bonding, furthermore to a bonding pad for the thermocompression bonding of a carrier material to a further carrier material, to a component comprising said bonding pad, and to a corresponding computer program product.

### SUMMARY

In order to be able to make electrical contact with contact terminals of a semiconductor structure, use is usually made of bonding pads applied to the respectively relevant contact terminals of the semiconductor structure. Bonding pads usually have a multilayered construction. In order to shape the bonding pad, a substructure is patterned, which is applied on the materials to be connected. A bonding metal is applied to the substructure.

By way of example, the publication by Tang et al. “Wafer-level Cu—Cu bonding technology” (Microelectronics Reliability 52 (2012) 312-320) discloses a layer construction composed of tantalum and copper. The publication by Huffman et al. “Fabrication and characterization of metal-to-metal interconnect structures for 3-D integration” (Journal of Instrumentation Volume 4 (2009)) discloses a layer construction composed of titanium and copper. Froemel et al. in their publication “Investigations of thermocompression bonding with thin metal layers” (Proceedings of transducers '11) disclose layer constructions composed of tantalum and copper, titanium and gold and of aluminum.

Against this background, the present disclosure presents a method for producing a bonding pad for thermocompression bonding, furthermore a bonding pad for the thermocompression bonding of a carrier material to a further carrier material, a component comprising said bonding pad, and finally a corresponding computer program product according to the description below. Advantageous configurations are evident from the following description.

Aluminum as bonding material, owing to use as standard interconnect material, would have to overcome the smallest hurdle in order to establish wafer bonding in industrial manufacturing, but requires a higher process temperature than gold and copper and, owing to the ready oxidation of aluminum, is regarded as a bonding system that is difficult to control. Gold and copper have hitherto been produced with a complex layer substructure comprising usually an adhesion layer, a diffusion barrier and e.g. a start layer for plating. Each of these layers requires a patterning, which leads to a complex process in which many parameters have to be coordinated with one another.

The disclosure is based on the insight that a bonding metal can be deposited directly onto an interconnect layer of a chip, wherein the interconnect layer in this case can fulfill a double function as electrical connection within the chip and as carrier of the bonding metal. A diffusion barrier as topmost layer can be integrated into the interconnect layer.

By depositing a single-layered bonding metal directly onto an interconnect layer of a chip, it is possible for time-intensive work steps to be obviated. A structural height of the bonding pad can be reduced, such that it is possible to achieve a smaller distance between chips bonded to one another.

The present disclosure provides a method for producing a bonding pad for thermocompression bonding, wherein the method comprises the following steps:

Providing a carrier material having semiconductor structures, wherein an outermost edge layer of the carrier material is embodied as a wiring metal layer for making electrical contact with the semiconductor structures; and

Depositing a single-layered bonding metal layer directly on a surface of the wiring metal layer in order to produce the bonding pad.

Furthermore, the present disclosure provides a bonding pad for the thermocompression bonding of a carrier material to a further carrier material, wherein the bonding pad comprises the following feature:

the carrier material, which has semiconductor structures, wherein an outermost edge layer of the carrier material is embodied as a wiring metal layer for making electrical contact with the semiconductor structures; and

a single-layered bonding metal layer, which is arranged directly on a surface of a wiring metal layer of the carrier material.

Furthermore, the present disclosure provides a component comprising the following features:

a first carrier material with at least one first bonding pad according to the approach presented here; and

a second carrier material with at least one second bonding pad according to the approach presented here, wherein the second bonding pad at least partly overlaps the first bonding pad, and the second bonding pad faces the first bonding pad, and is cohesively connected to the first bonding pad by means of a bonding process.

A bonding pad can be understood to be a connecting element configured to form a cohesive connection with a further bonding pad during a bonding process for thermocompression bonding. The bonding process in this case is a thermal process in which a material of the bonding pad is heated to a bonding temperature in order to enable growth of crystals and/or crystallites over a contact area between two bonding pads. In this case, the bonding temperature is lower than a liquidus temperature of the material. The bonding pads are pressed onto one another with a contact pressure during the bonding process. A carrier material can be a chip or a wafer. The carrier material can comprise a semiconductor material. Semiconductor structures can be, for example, integrated circuits or micromechanical sensors. A wiring metal layer can be an electrically conductive metallic and/or ceramic layer from which interconnects for interconnecting the semiconductor structures, for example, can be formed. Depositing can be understood to be addition of material constituents to the surface. A layer having a predetermined layer thickness can be formed during the depositing process. The layer thickness can be deposited uniformly over an area on which the bonding metal is deposited.

The first bonding pad and the second bonding pad can each be embodied as at least one bonding contact for electrically connecting the first carrier material and the second carrying material. Alternatively or additionally, the first bonding pad and the second bonding pad can also each be embodied as a bonding frame for sealing a cavity between the first carrier material and the second carrier material. If the two carrier materials are connected in a predetermined atmosphere, the atmosphere can be maintained within the bonding frame between the carrier materials. By way of example, the carrier materials can be connected under a vacuum. There can then be an evacuated space within the bonding frame even after removal from the vacuum. By way of example, it is thus possible to provide a reference pressure chamber for a pressure sensor.

The carrier material can be provided with a wiring metal layer composed of an Al-based electrical conductor material. Alternatively, or supplementarily, a Cu-based or an Au-based metal layer can be deposited as the bonding metal layer. An Al-based material can be understood to be a material which at least partly comprises aluminum (Al). A Cu-based material can be understood to be a material which at least partly comprises copper (Cu). An Au-based material can be understood to be a material which at least partly comprises gold (Au). By way of example, the wiring metal layer can consist of pure Al, AlSi, AlSiCu, AlCu, wherein these can be enclosed at the top and bottom by diffusion barrier layers such as e.g. Ti/TiN or Ta/TaN, that is to say e.g. Ti/TiN/AlCu/Ti/TiN. By way of example, the bonding metal layer can be deposited as pure copper (Cu) or pure gold (Au). Al-based interconnects can be processed particularly simply. Cu and Au have corrosion-resistant properties. By way of example, the bonding metal layer can be deposited electrolytically or by a sputtering method. A very uniformly thin layer thickness can be produced as a result.

The method can comprise a masking step, wherein in the masking step at least one mask region to be kept free on the surface of the wiring metal layer is covered with a masking layer, wherein in the depositing step the bonding metal layer is deposited in an unmasked region of the surface of the wiring metal layer. The unmasked region can be left free with a predetermined width, for example a width of between 0.1 μm and 1000 μm, in particular a width of between 1 μm and 500 μm. The method can comprise, in particular, a removing step, wherein the masking layer is removed in the removing step. Masking can be understood to be a process of coating the surface with a photosensitive resist, for example, which cures in exposed regions. Working regions can be arranged in unexposed regions, in which working regions the resist is not cured and can be removed. In the working regions, the surface is then uncovered and can be processed further. In the depositing step, the bonding metal can be deposited selectively in the uncovered regions. By means of a delimitation of the areas for deposition, the bonding pad can be arranged and shaped in a targeted manner. Valuable noble metal can thus be saved.

At least one sealing region can be left free on the surface of the wiring metal layer for depositing the bonding metal layer, wherein the sealing region has a contour closed in a ring-shaped fashion. A sealing region can be a continuous delimiting structure of a region to be sealed. The sealing region can enclose contours of functional elements in the region. The sealing region can provide a closed-off cavity between two carrier materials arranged in an adjacent fashion.

In an alternative variant of the method, the carrier material can be provided with an unpatterned wiring metal layer. Following a preceding step of removing the masking layer, in a further step of masking a further masking layer can be applied to the bonding metal layer and parts of the wiring metal layer. In a patterning step the wiring metal layer can be removed at unmasked locations. The further masking layer can subsequently be removed in a further step of removing. On account of a continuous wiring metal layer, the bonding metal layer can be deposited electrochemically, in particular. Particularly smooth and/or uniform layer thicknesses of the bonding metal can be produced by an electrochemical deposition method. The layer thickness can be defined precisely. During patterning, the wiring metal layer can be etched, for example.

The carrier material can be provided with a patterned wiring metal layer. If the wiring metal layer is provided such that it is already patterned, a wet-chemical deposition method, in particular, can be used for depositing the bonding metal layer. By means of a wet-chemical method, the bonding metal layer can be deposited with a predetermined composition. In the case of the wet-chemical method, it is not necessary to make electrical contact with regions for deposition.

The surface of the wiring metal layer can be provided with a diffusion barrier. By way of example, TiN, TaN or TiW can be incorporated into the surface of the wiring metal over the whole area in order to prevent diffusion processes during bonding and afterward.

The carrier material can be provided with at least one microelectromechanical structure with which electrical contact is made by at least one partial region of the wiring metal layer. A microelectromechanical structure can have movable regions that can be produced by means of fabrication steps appertaining to semiconductor technology. The microelectromechanical structure can be arranged within the sealing region. The microelectromechanical structure can be part of a sensor, for example of a pressure sensor or acceleration sensor.

The method can comprise a step of conditioning the bonding metal layer. During conditioning an exposed surface of the bonding metal layer can be prepared for a subsequent bonding process. By way of example, conditioning can be understood to be smoothing, cleaning or leveling of the layer thickness. The bonding process can be improved by conditioning. A quality of the bonding collection can be increased as a result. By way of example, a hermetic seal of the sealing region can be achieved by conditioning even in the case where the sealing region has a small width. Bonding metal and chip area can be saved as a result.

The carrier material can be provided with a wiring metal layer having a predetermined thickness, for example a thickness of between 0.01 μm and 200 μm, in particular a thickness of between 0.1 μm and 20 μm. The bonding metal layer can be deposited with a predetermined thickness, for example a thickness of between 0.001 μm and 10 μm, in particular a thickness of between 0.01 μm and 1.0 μm. By means of such predetermined layer thicknesses it is possible to limit a crystallite size within the layer. In the case of smaller crystallites, a material can have, compared with an average state, improved material properties such as, for example, increased tensile strength and/or greater hardness. Small crystallites can provide, during the bonding process, many start seeds for crystal growth beyond an interface.

Also advantageous is a computer program product having program code which can be stored on a machine-readable carrier such as a semiconductor memory, a hard disk storage unit or an optical storage unit and is used for carrying out or controlling steps of the method according to any of the above-described embodiments when the program product is executed on a computer or a device.

### BRIEF DESCRIPTION OF THE DRAWINGS

The disclosure is explained in greater detail by way of example below with reference to the accompanying drawings, in which:

FIG. 1 shows a sectional illustration through a bonding pad in accordance with an exemplary embodiment of the present disclosure;

FIG. 2 shows a flow chart of a method for producing a bonding pad in accordance with an exemplary embodiment of the present disclosure;

FIG. 3 shows a sectional illustration through a provided carrier material in accordance with an exemplary embodiment of the present disclosure;

FIG. 4 shows a sectional illustration through the carrier material after application of the masking layer in accordance with an exemplary embodiment of the present disclosure;

FIG. 5 shows a sectional illustration through the masked carrier material after a step of depositing the bonding metal in accordance with an exemplary embodiment of the present disclosure;

FIG. 6 shows a sectional illustration through the carrier material after the step of depositing the bonding metal and removing the masking layer in accordance with an exemplary embodiment of the present disclosure;

FIG. 7 shows a sectional illustration through the carrier material after the step of applying a further masking layer in accordance with an exemplary embodiment of the present disclosure;

FIG. 8 shows a sectional illustration through the masked carrier material and bonding metal after the step of patterning the wiring metal layer in accordance with an exemplary embodiment of the present disclosure;

FIG. 9 shows a sectional illustration through two carrier materials with applied bonding metal and patterned wiring metal layer in accordance with an exemplary embodiment of the present disclosure;

FIG. 10 shows a sectional illustration through a component comprising two carrier materials bonded to one another in accordance with an exemplary embodiment of the present disclosure;

FIG. 11 shows a sectional illustration through another provided carrier material with patterned wiring metal layer in accordance with a further exemplary embodiment of the present disclosure;

FIG. 12 shows a sectional illustration through the other carrier material now with applied masking layer in accordance with a further exemplary embodiment of the present disclosure;

FIG. 13 shows a sectional illustration through the other, now masked carrier material with now deposited bonding metal in accordance with a further exemplary embodiment of the present disclosure;

FIG. 14 shows a sectional illustration through two carrier materials with applied bonding metal in accordance with an exemplary embodiment of the present disclosure;

FIG. 15 shows a sectional illustration through a component comprising two carrier materials bonded to one another in accordance with an exemplary embodiment of the present disclosure; and

FIG. 16 shows an illustration of a carrier material with a functional region and a circumferential sealing region in accordance with an exemplary embodiment of the present disclosure.

In the following description of preferred exemplary embodiments of the present disclosure, identical or similar reference signs are used for the similarly acting elements illustrated in the different figures, a repeated description of these elements being dispensed with.

### DETAILED DESCRIPTION

FIG. 1 shows a sectional illustration through a bonding pad 100 in accordance with an exemplary embodiment of the present disclosure. The bonding pad 100 is configured to connect a carrier material 102 to a further carrier material (not illustrated), by means of a thermocompression bonding method. The bonding pad 100 has a single-layered bonding metal layer 104, which is arranged directly on a surface of a wiring metal layer 106 of the carrier material 102. The wiring metal layer 106 can be just single-layered, for example, and forms an outermost edge layer of the carrier material 102. The carrier material 102 is formed, for example, by a wafer or chip having semiconductor structures (not shown) with which electrical contact is made by the wiring metal layer 106. FIG. 1 illustrates an excerpt from the carrier material 102. In the exemplary embodiment illustrated, the wiring metal layer 106 is arranged on the carrier material 102 over a large area. The wiring metal layer 106 is embodied as an aluminum-based interconnect material. The bonding metal layer 104 consists of gold or copper and has been deposited electrochemically or wet-chemically on the wiring metal 106. The bonding metal layer 104 has a thickness of between 0.01 μm and 1.0 μm. The bonding metal layer 104 has a lateral width between 1 μm and 500 μm. The wiring metal layer 106 has a thickness of between 0.1 μm and 20 μm.

In other words, FIG. 1 shows a layer construction for a thermocompression bonding method. The thermocompression bonding method as a technique for connecting two wafers 102 can be carried out with a multiplicity of different layer constructions.

The layer system described in FIG. 1 considerably reduces the outlay for patterning the bonding connection, as a result of which a more cost-effective, more efficient production process with fewer sources of faults than hitherto is possible. The bonding connection at the same time constitutes a mechanically stable, hermetic and electrical connection, and can thus fulfill up to three functions by means of only one bonding step.

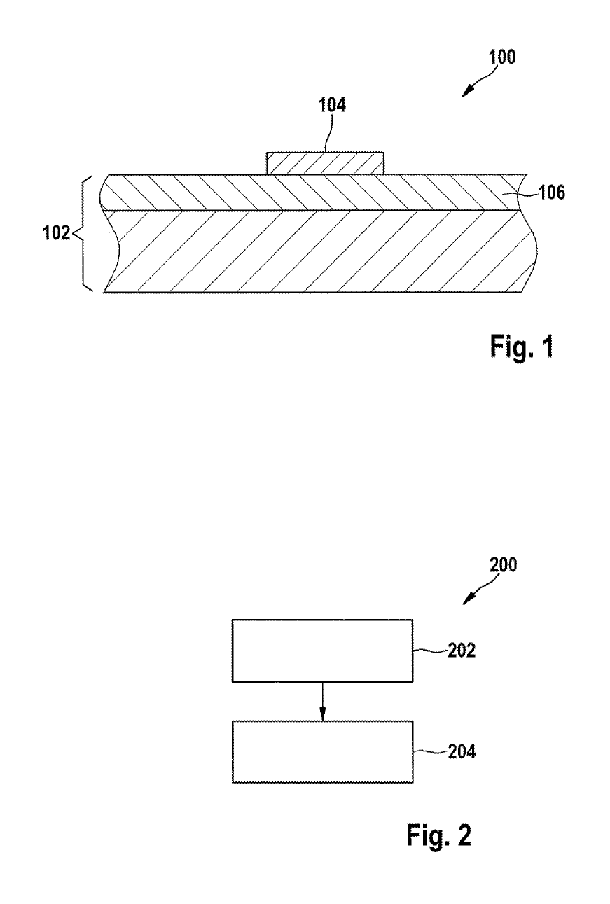

FIG. 2 shows a flow chart of a method 200 for producing a bonding pad in accordance with an exemplary embodiment of the present disclosure. The method 200 comprises at least a step of providing 202 and a step of depositing 204. The step 202 of providing involves providing a carrier material having semiconductor structures. An outermost edge layer of the carrier material is embodied as a wiring metal layer for making electrical contact with the semiconductor structures. The step 204 of depositing involves depositing a single-layered bonding metal layer directly on a surface of the wiring metal layer in order to produce the bonding pad. In step 204, the bonding metal layer can be plated electrochemically or wet-chemically.

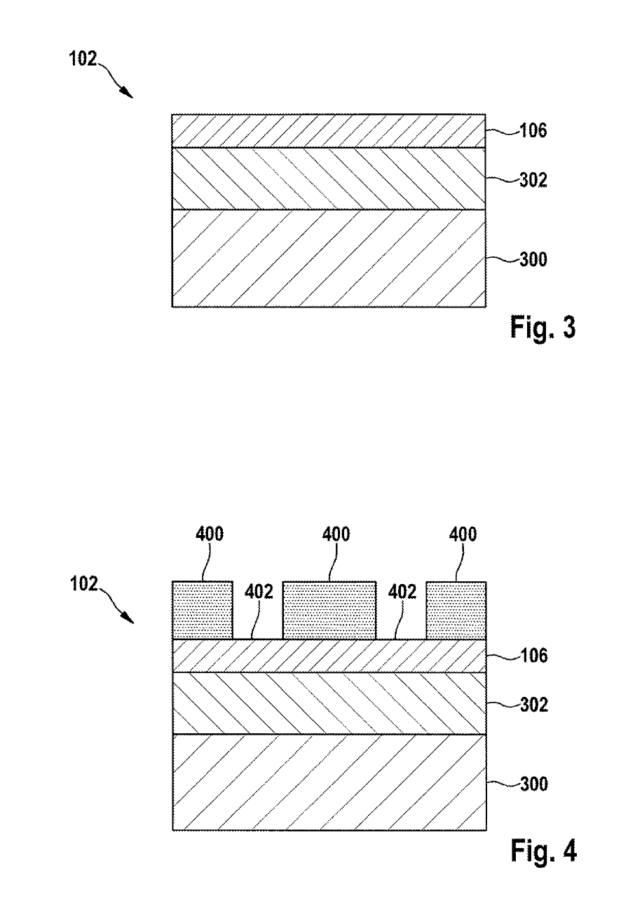

The method 200 can be implemented in at least two variants. In a first variant using electrochemical plating, the method 200 for connecting two substrates can comprise the following process steps that can be carried out on the at least two substrates to be connected to one another. The initial state is a substrate areally coated with the wiring metal, with a possible layer substructure. A step of applying and patterning involves applying and patterning a non-conductive masking layer e.g. composed of photoresist, polyimide, silicon nitride. A step of depositing 204 involves depositing a bonding metal layer e.g. by means of an electrochemical deposition method. The masking layer is removed again in a step of removing. A second masking layer can optionally be applied in a step of applying. The wiring metal can be patterned, e.g. by means of plasma etching, in a step of patterning. The second masking layer can optionally be removed in a step of removing. The at least two substrates are connected in a step of thermocompression bonding. The steps of variant 1 are illustrated in FIGS. 3 to 10.

In a second variant using chemical plating, the method 200 for connecting two substrates can comprise the following process steps that are carried out on the at least two substrates to be connected to one another. The initial state is a patterned wiring metal layer on a substrate, with a possible layer substructure. An optional step of applying and patterning a non-conductive masking layer, e.g. composed of photoresist, polyimide, silicon nitride. A step of depositing 204 the bonding metal layer, e.g. by means of a chemical deposition method. Optionally a step of removing the masking layer, and a step of thermocompression bonding of the at least two substrates. The steps of variant 2 are illustrated in FIGS. 11 to 15.

Further process steps are optionally possible. It is possible to carry out a step of cleaning/conditioning the bonding metal surfaces e.g. by means of a plasma treatment (e.g. Ar backsputtering) and/or a gas treatment (e.g. with forming gas) and/or a vapor treatment (e.g. with formic acid) and/or wet-chemical cleaning before and/or during bonding. It is possible to carry out a step of heat treatment for post-bond annealing for strengthening the bond adhesion. The method 200 can comprise a step of applying and patterning further layers before bonding.

The wafer bonding connection described or the method can be used for producing sensors with capping, such as e.g. infrared sensor arrays, acceleration sensors, rate-of-rotation sensors, pressure sensors.

A separate start layer for the deposition of the bonding metal layer is advantageously obviated according to the approach presented here. Small crystallite sizes are achieved by means of a thin bonding layer. Small crystallites allow rapid rearrangement at an interface of the bonding pads and hence a robust bonding connection. Smooth surfaces can be achieved by means of electrodepositions. The approach presented here makes it possible to produce a cost-effective, corrosion-resistant bonding connection which enables a defined distance between two substrates.

It is advantageous for the thermocompression bonding if the bonding surfaces are as smooth as possible and all lie on one plane, since then large regions of the bonding areas initially come into contact during the bonding process. Electrochemical deposition methods are particularly well suited to producing smooth surfaces. They additionally make it possible to coat selectively determined regions and to realize both very thin layers having a thickness of a few nanometers (nm) and very thick layers having a thickness of a number of micrometers (μm).

During the thermocompression bonding, (re-)crystallization and grain growth of grains occur at the contact areas as a result of (inter-)diffusion processes on both sides of the bonding area, which leads to the adhesion of the bonding interfaces to one another. In the case of thin layers, the grains are significantly smaller than in the case of thick layers and rearrangement during bonding can take place more rapidly and more completely than in the case of thick layers. Bonding connections which can proceed at low temperatures and which nevertheless subsequently withstand high temperatures are advantageous, moreover, for reasons of process compatibilities. Bonding metals having low diffusion energies, which is usually accompanied by low bond energies and melting points, are therefore of particular interest.

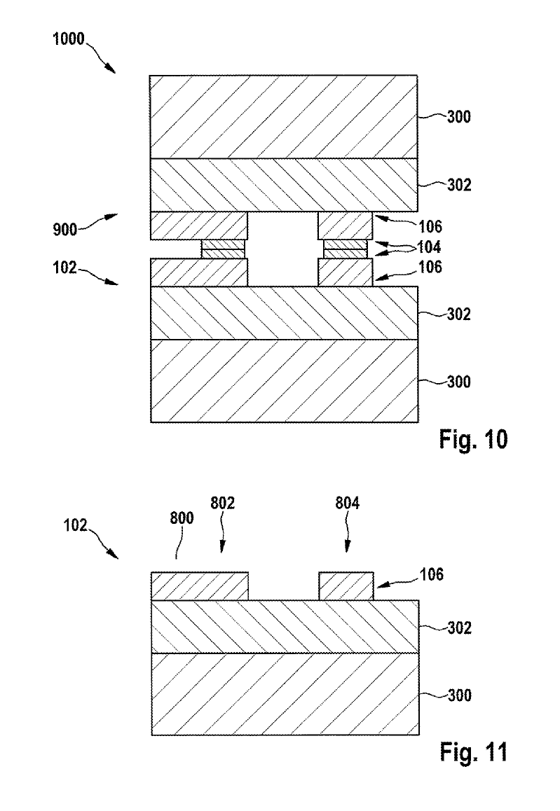

FIGS. 3 to 10 show illustrations of semifinished products (or of the finished bonding pad in FIG. 10) which were obtained after the performance of steps of a process flow corresponding to the abovementioned first variant of the method 200 for producing a bonding pad 100 in accordance with an exemplary embodiment of the present disclosure. The illustrations show product stages obtained after the performance of process steps using electrochemical plating in detail view cross sections through one of the bonding contacts such as is illustrated in FIG. 16.

FIG. 3 shows a sectional illustration through a provided carrier material 102 for use in an exemplary embodiment of the present disclosure. The carrier material 102 is illustrated in a state in which it is provided for a method for producing a bonding pad in accordance with an exemplary embodiment of the present disclosure. FIG. 3 illustrates a partial region of a wafer or chip which is formed by the carrier material 102. The carrier material 102 extends beyond the illustrated partial region in a plane perpendicular to an illustration plane of the sectional illustration. The carrier material 102 comprises a substrate 300 composed of, for example, crystalline silicon. A layer substructure 302 is arranged on the substrate 300, which layer substructure can comprise constituent parts of semiconductor structures (such as, for example, a microchemical sensor). The layer substructure 302 can also have an adhesion promoting layer in order to enable a fixed connection to an outermost edge layer 106 of the carrier material 102 composed of a wiring metal. The wiring metal layer 106 or wiring metal plane 106 is aluminum-based and consists, for example, of pure aluminum or AlSi, AlSiCu, AlCu or Ti/TiN/AlCu/Ti/TiN. Further Al-based metals or alloys or layer sequences are possible.

FIG. 4 shows a sectional illustration through a carrier material 102 with applied masking layer 400 in accordance with an exemplary embodiment of the present disclosure. The carrier material 102 corresponds to the carrier material in FIG. 3 and comprises a substrate 300, a layer substructure 302 and a wiring metal plane 106. The masking layer 400 has been applied to the wiring metal layer 106 in a process step of masking and has subsequently been patterned. The masking layer 400 is electrically insulating in this exemplary embodiment. By way of example, the masking layer 400 is applied as photosensitive resist for a photolithographic method. Partial regions of the resist are subsequently exposed. Depending on the resist used, afterward the exposed or unexposed partial regions of the resist are removed and unmasked regions 402, in which the surface of the wiring metal 106 is uncovered, are produced.

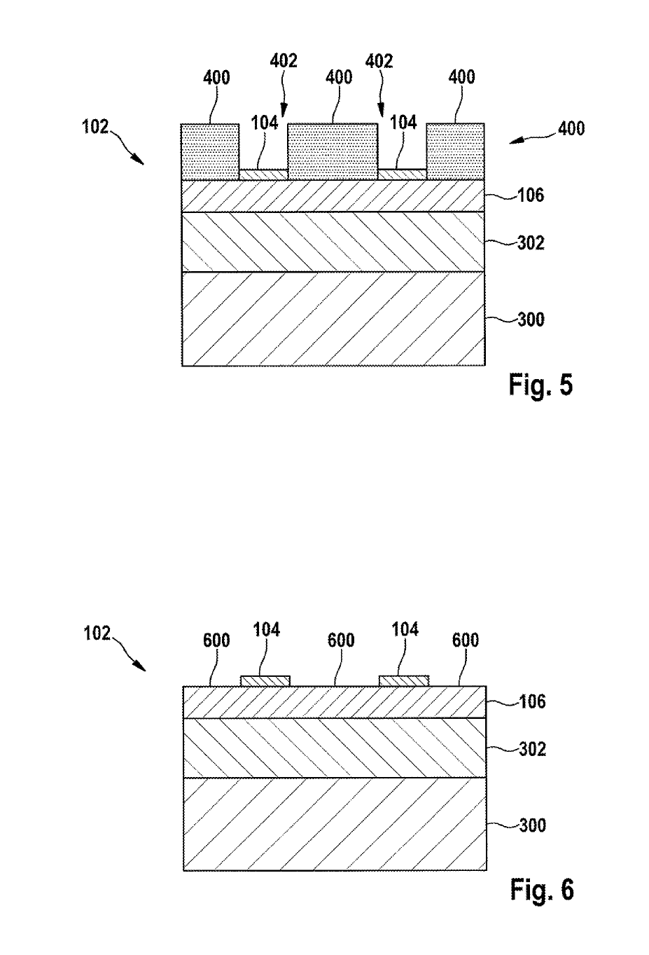

FIG. 5 shows a sectional illustration through a masked carrier material 102 with deposited bonding metal 104 in accordance with an exemplary embodiment of the present disclosure. The carrier material 102 corresponds to the carrier material illustrated in FIG. 4. In the unmasked region 402, the bonding metal layer 104 has been deposited directly onto the surface of the wiring metal 106 in a step of depositing. No bonding metal has been deposited at locations covered with the masking layer 400. The depositing has been carried out electrochemically in this exemplary embodiment. For this purpose, an electrical potential has been applied to the continuous wiring metal layer 106, and a resulting electric field has drawn gold ions or copper ions from a plating bath to the uncovered surface of the wiring metal 106, where they are deposited as metal layer 104. A plating duration and further process parameters such as e.g. a flow rate of an electrolyte and a current intensity determine a layer thickness of the bonding metal layer 104.

FIG. 6 shows a sectional illustration through a carrier material 102 with deposited bonding metal 104 and removed masking layer in accordance with an exemplary embodiment of the present disclosure. The carrier material 102 corresponds to the carrier material illustrated in FIG. 5. The masking layer has been removed in a step of removing. The masked partial regions 600 of the surface of the wiring metal layer are uncovered again.

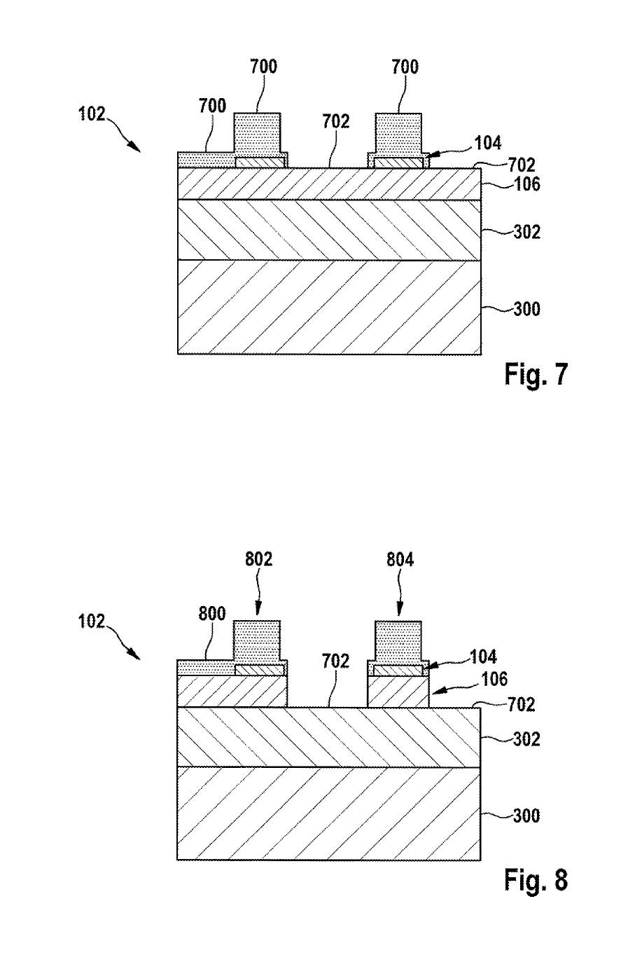

FIG. 7 shows a sectional illustration through a carrier material 102 with applied further masking layer 700 in accordance with an exemplary embodiment of the present disclosure. The carrier material 102 corresponds to the carrier material illustrated in FIG. 6. The second masking layer 700 has been applied and patterned in a further step of masking, as described for example in FIG. 4. The bonding metal layer 104 and a partial region of the surface of the wiring metal layer 106 are covered by the further masking layer 700. The remaining surface 702 of the wiring metal 106 is uncovered.

FIG. 8 shows a sectional illustration through a masked carrier material 102 and bonding metal 104 with patterned wiring metal layer 106 in accordance with an exemplary embodiment of the present disclosure. The carrier material 102 corresponds to the carrier material illustrated in FIG. 7. In a step of patterning, the wiring plane 106 has been removed in the unmasked regions 702. The layer substructure 302 is uncovered in the unmasked regions 702. Thus, an interconnect 800 has been fashioned from the wiring plane 106 in the illustrated excerpt, said interconnect electrically conductively connecting a bonding contact 802 to a semiconductor structure of the carrier material 102. Furthermore, a base for a sealing region 804 has been fashioned from the wiring plane 106. The bonding metal layers 104 of the bonding contact 802 and of the sealing region 804 are arranged in one plane.

In other words, FIG. 8 shows a metal system. It consists of a wiring plane 106 (e.g. Al, AlSi, AlSiCu, AlCu, Ti/TiN/AlCu/Ti/TiN) and at least one overlying bonding metal layer 104 (e.g. Au, Cu). The metal system can be demonstrated by cross-section preparation and other physical methods in widespread use. The metal system presented here can be used in all applications in which a mechanically stable connection and/or a hermetic seal and/or an electrical contact between at least two wafers or chips 102 or a wafer 102 and a chip 102 are/is intended to be provided. This may be the case e.g. in the production of infrared sensor arrays, acceleration sensors, rate-of-rotation sensors, pressure sensors.

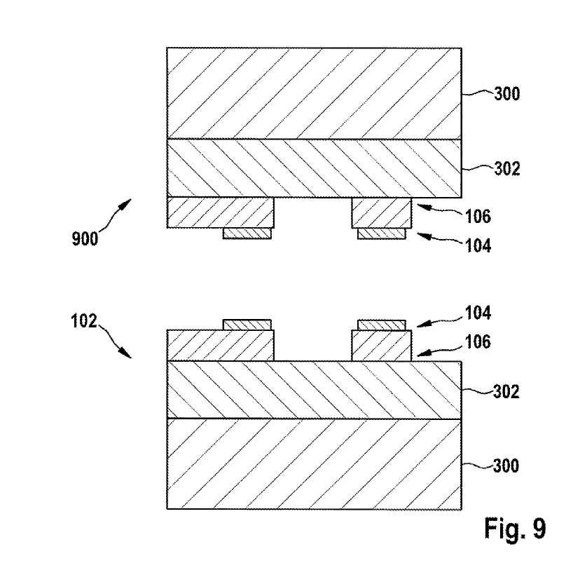

FIG. 9 shows a sectional illustration through two carrying materials 102, 900 with applied bonding metal 104 and patterned wiring metal layer 106 in accordance with an exemplary embodiment of the present disclosure. A first carrier material 102 corresponds to the carrier material illustrated in FIG. 7. In a step of removing, the further masking layer has been removed and the bonding metal layer 104 is uncovered again. The bonding contact and the sealing region project above the wiring metal layer by a material thickness of the bonding metal. A second carrier material 900 is embodied in a manner mirror-inverted with respect to the first carrier material 102. The second carrier material 900 has a contour which, within a tolerance range, is mirror-inverted with respect to the first carrier material 102. The bonding metal layer 104 of the second carrier material 900 faces the bonding metal layer 104 of the first carrier material 102 and is aligned congruently with respect thereto. There is a distance between the first carrier material 102 and the second carrier material 900.

FIG. 10 shows a sectional illustration through a component 1000 comprising two carrier materials 102, 900 bonded to one another in accordance with an exemplary embodiment of the present disclosure. The carrier materials 102, 900 correspond to the carrier materials in FIG. 9. The bonding metal layers 104 of the carrier materials 102, 900 bear directly against one another. In a step of bonding or of thermocompression bonding, the bonding metal layers have been connected to one another and crystals have grown over an interface between the bonding metal layers 104. The two carrier materials 102, 900 are at a predetermined distance from one another.

In other words, FIG. 10 shows a component 1000 consisting of at least two substrates 102, 900 (e.g. wafers, chips) which are connected to one another by means of a metallic wafer bonding connection. The metallic wafer bonding connection consists of at least one bonding metal layer 104 (e.g. Au, Cu) situated on a wiring plane 106 (e.g. composed of Al, AlSi, AlSiCu, AlCu optionally with a diffusion barrier situated therebetween, e.g. composed of TiN, TaN or TiW). The metallic wafer bonding connection layer 104 can be used for the wiring of at least one of the substrates 102, 900. The metallic wafer bonding connection layer 104 can be elevated relative to the further layers on at least one of the substrates 102, 900. The metallic wafer bonding connection can provide at least a mechanically stable connection and/or an electrical connection 802 and/or optionally a hermetic, closed sealing connection 804 (“bonding frame”) between the at least two substrates 102, 900. An MEMS component can be integrated on at least one of the substrates 102, 900. The surfaces of the wafer bonding metallizations 104 can in each case be elevated in the regions 802, 804 provided for bonding for the mechanically stable and/or electrical and/or hermetic connection on the substrates 102, 900 and can be at the same level, e.g. by virtue of the fact that they have the same layer substructure and/or the surface is planarized before or after the application of the wafer bonding metallizations 104. The metallic wafer bonding connection can have lateral structure widths in at least one direction of between 1 μm and 500 μm. By means of the metallic wafer bonding connection it is possible to set a defined distance of 0.1 μm to 20 μm between the at least two substrates 102, 900. The wiring plane 106 can have a thickness of 0.1 μm to 20 μm and the bonding metal layer 104 can have a thickness of preferably 0.01 μm to 1.0 μm.

FIGS. 11 to 14 show illustrations of semifinished products (or of the finished bonding pad) which were obtained after the performance of steps of a process flow corresponding to variant 2 of the method 200 for producing a bonding pad 100 in accordance with an exemplary embodiment of the present disclosure. The illustrations show the process stages before and after the performance of the process steps for chemical plating in detail view cross sections through one of the bonding contacts such as is illustrated in FIG. 16.

FIG. 11 shows a sectional illustration through a provided carrier material 102 with patterned wiring metal layer 106 in accordance with a further exemplary embodiment of the present disclosure. The carrier material 102 corresponds to the carrier material in FIG. 3 and comprises a substrate 300, a layer substructure 302 and a wiring metal plane 106. In contrast to FIG. 3, the wiring metal plane 106 has already been patterned and shaped as a region for a bonding contact 802 and for a sealing region 804.

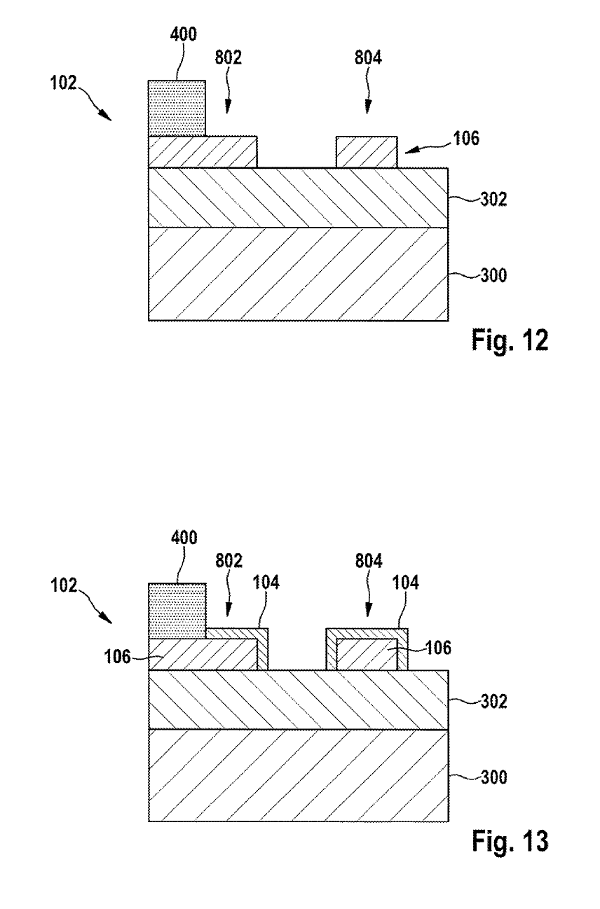

FIG. 12 shows a sectional illustration through a carrier material 102 with applied masking layer 400 in accordance with a further exemplary embodiment of the present disclosure. The carrier material 102 corresponds to the carrier material in FIG. 11. The masking layer 400 has been applied and patterned in a step of masking. An interconnect of the wiring metal layer 106 which connects the bonding contact region 802 to a semiconductor structure of the carrier material 102 has been masked. The wiring metal 106 is uncovered in the bonding contact region 802 and in the sealing region 804.

FIG. 13 shows a sectional illustration through a masked carrier material 102 with deposited bonding metal 104 in accordance with a further exemplary embodiment of the present disclosure. The carrier material 102 corresponds to the carrier material in FIG. 12. On the wiring plane 106, the bonding metal 104 has been deposited in the uncovered regions 802 and 804 in a step of depositing. In contrast to the exemplary embodiment in FIG. 5, the bonding metal 104 has also been deposited on side surfaces of the wiring metal 106. The depositing has been carried out using a wet-chemical process. No bonding metal has been deposited on the layer substructure 302.

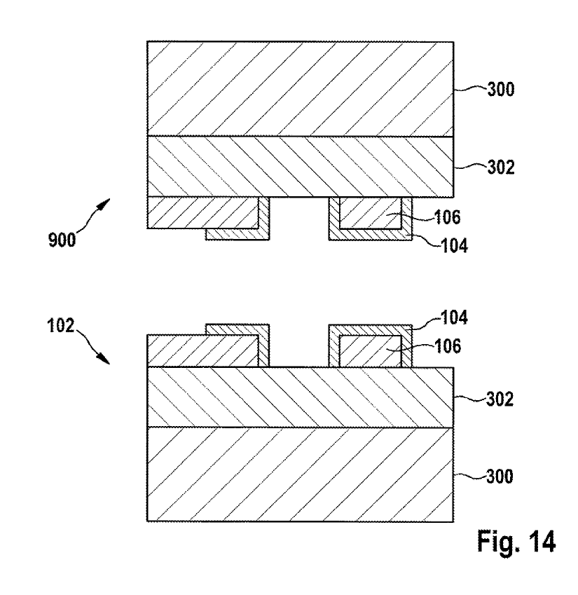

FIG. 14 shows a sectional illustration through two carrier materials 102, 900 with applied bonding metal 104 in accordance with a further exemplary embodiment of the present disclosure. The carrier material 102 corresponds to the carrier material in FIG. 13. In a removing step, the masking layer has been removed from the interconnect. The bonding metal layer 104 projects above the wiring plane 106. A second carrier material 900 has an at least partly overlapping contour with respect to the first carrier material 102 within a tolerance range. The bonding metal layer 104 of the second carrier material 900 faces the bonding metal layer 104 of the first carrier material 102. There is a distance between the first carrier material 102 and the second carrier material 900.

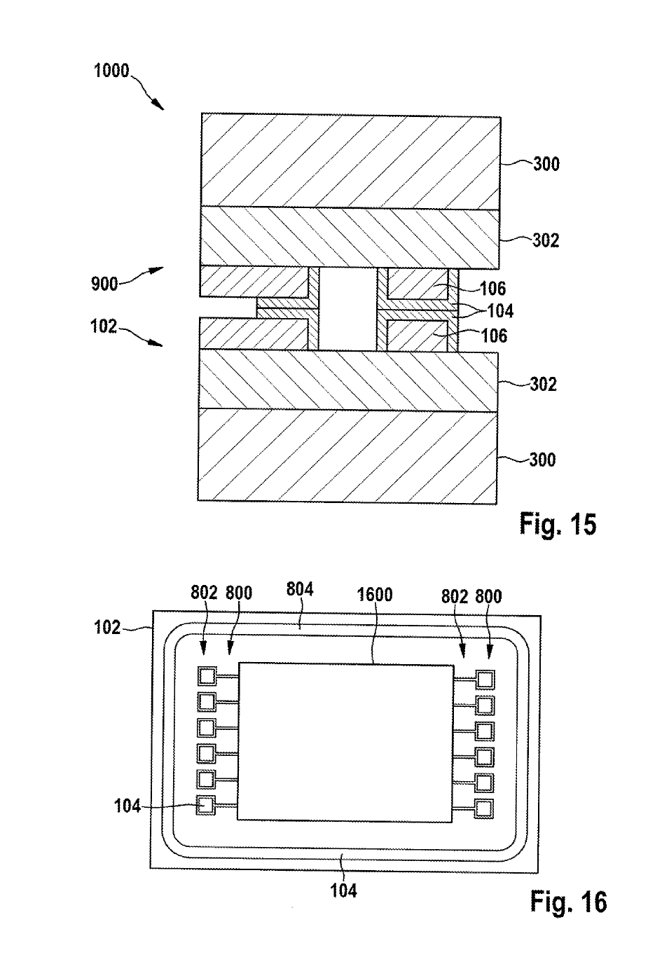

FIG. 15 shows a sectional illustration through a component 1000 comprising two carrier materials 102, 900 bonded to one another in accordance with an exemplary embodiment of the present disclosure. The carrier materials 102, 900 correspond to the carrier materials in FIG. 14. The bonding metal layers 104 of the carrier materials 102, 900 bear directly against one another. In a step of bonding or of thermocompression bonding, the bonding metal layers have been connected to one another and crystals have grown over an interface between the bonding metal layers 104. The two carrier materials 102, 900 are at a predetermined distance from one another.

FIG. 16 shows an illustration of a carrier material 102 with a functional region 1600 and a circumferential sealing region 804 in accordance with an exemplary embodiment of the present disclosure. In this exemplary embodiment, the functional region 1600 is at least part of a microelectromechanical system (MEMS) 1600. By way of example, a further part of the MEMS 1600 can be arranged on a further carrier material embodied in a mirror-inverted fashion. The functional region 1600 has a rectangular form and has in each case six terminals on opposite narrow sides, said terminals being connected to a respective bonding contact 802 by means of interconnects 800 such as, for example, the interconnect illustrated in FIG. 8. A sealing region 804 is arranged circumferentially in a manner closed in a ring-shaped fashion around the MEMS 1600. The sealing region 804 is at a distance from the functional region 1600 and the bonding contacts 802. The sealing region 804 has rounded corners. The sealing region 804 and the bonding contacts 802 are coated with a single-layered bonding metal layer 104, which has been deposited directly on an underlying wiring metal layer. The sealing region 804 and the bonding contacts 802 are arranged in one plane and project above a plane of the MEMS 1600.

In other words, FIG. 16 shows a plan view of a typical component arrangement on a side of the component as illustrated in FIGS. 9 and 14. The bonding regions 802, 804 have a bonding metallization 104. The illustrations in FIGS. 13 to 15 show sections along a sectional line through one of the interconnects 800, one of the bonding contacts 802 and the sealing region 804.

The exemplary embodiments described and shown in the figures have been chosen merely by way of example. Different exemplary embodiments can be combined with one another completely or with regard to individual features. An exemplary embodiment can also be supplemented by features of a further exemplary embodiment.

Furthermore, method steps according to the disclosure can be repeated and performed in a different order than that described.

If an exemplary embodiment comprises an “and/or” link between a first feature and second feature, then this should be interpreted such that the exemplary embodiment has both the first feature and the second feature in accordance with one embodiment and either only the first feature or only the second feature in accordance with a further embodiment.

What is claimed is:

1. A method for producing a bonding pad for thermocompression bonding, the method comprising:
depositing a single-layered bonding metal layer directly on a surface of a wiring metal layer,
wherein the wiring metal layer is an outermost edge layer of a carrier material, the carrier material having semiconductor structures, and
wherein the wiring metal layer is configured to make electrical contact with the semiconductor structures.

2. The method according to claim 1, wherein the wiring metal layer is composed of an Al-based electrical conductor material and/or has a diffusion barrier situated on the wiring metal layer, and/or at least one Cu-based or one Au-based metal layer is deposited as the bonding metal layer.

3. The method according to claim 1, further comprising:
covering at least one mask region on the surface with a masking layer,
wherein depositing a single-layered bonding metal layer includes depositing the single-layered bonding metal layer in an unmasked region of the surface.

4. The method according to claim 3, wherein covering at least one mask region includes leaving at least one sealing region free on the surface, the at least one sealing region having a contour closed in a ring-shaped fashion.

5. The method according to claim 3, further comprising:
removing the masking layer;
applying a further masking layer to the bonding metal layer and parts of the wiring metal layer; and
removing the wiring metal layer at unmasked locations,
wherein the wiring metal layer is an unpatterend wiring metal layer.

6. The method according to claim 1, wherein the wiring metal layer is a patterned wiring metal layer.

7. The method according to claim 1, wherein the carrier material includes at least one microelectromechanical structure with which electrical contact is made by at least one partial region of the wiring metal layer.

8. The method according to claim 1, further comprising:
conditioning the bonding metal layer including preparing an exposed surface of the bonding metal layer for a subsequent bonding process.

9. The method according to claim 1, wherein the wiring metal layer has a predetermined thickness and/or the bonding metal layer is deposited with a predetermined thickness.

10. A bonding pad for thermocompression bonding of a carrier material to a further carrier material, wherein the bonding pad comprises:
the carrier material with semiconductor structures, wherein an outermost edge layer of the carrier material is a wiring metal layer configured to make electrical contact with the semiconductor structures; and
a single-layered bonding metal layer, which is arranged directly on a surface of the wiring metal layer of the carrier material.

11. A component, comprising:
a first carrier material with at least one first bonding pad including a carrier material with semiconductor structures, an outermost edge layer of the carrier material being a wiring metal layer configured to make electrical contact with the semiconductor structures, the at least one first bonding pad further including a single-layered bonding metal layer arranged directly on a surface of the wiring metal layer of the carrier material; and
a second carrier material with at least one second bonding pad including a carrier material with semiconductor structures, an outermost edge layer of the carrier material being a wiring metal layer configured to make electrical contact with the semiconductor structures, the at least one second bonding pad a single-layered bonding metal layer arranged directly on a surface of the wiring metal layer of the carrier material,
wherein the at least one second bonding pad, within a tolerance range with respect to the at least one first bonding pad, at least partly overlaps the at least one first bonding pad, and the at least one second bonding pad faces the at least one first bonding pad, and is cohesively connected to the at least one first bonding pad by a bonding process.

12. The component according to claim 11, wherein the at least one first bonding pad and the at least one second bonding pad are each at least one bonding contact configured to electrically connect the first carrier material and the second carrier material and/or wherein the at least one first bonding pad and the at least one second bonding pad are each a bonding frame configured to seal a cavity between the first carrier material and the second carrier material and/or wherein the at least one first bonding pad and the at least one second bonding pad are each at least one bonding contact configured to mechanically connect the first carrier material and the second carrier material.

13. A computer program product having program code for controlling or implementing the method according to claim 1 when the program product is executed on a device.
